(19) United States
(12) Patent Application Publication
(10) Pub. No.: US 2024/0274623 A1
(43) Pub. Date: Aug. 15, 2024

(54) ARRAY SUBSTRATE AND METHOD FOR MANUFACTURING THE SAME, DISPLAY PANEL AND DISPLAY DEVICE

(71) Applicant: XIAMEN TIANMA OPTOELECTRONICS CO., LTD., Xiamen (CN)

(72) Inventors: Changgang WU, Xiamen (CN); Xuhui PENG, Shanghai (CN); Jiaqi KANG, Xiamen (CN); Xiaoxia HONG, Xiamen (CN); Zhe PIAO, Xiamen (CN); Yiwei WU, Xiamen (CN); Pan JIN, Wuhan (CN); Zhen WU, Xiamen (CN)

(73) Assignee: XIAMEN TIANMA OPTOELECTRONICS CO., LTD., Xiamen (CN)

(21) Appl. No.: 18/642,841

(22) Filed: Apr. 23, 2024

(30) Foreign Application Priority Data
Jan. 25, 2024 (CN) 202410109528.6

(51) Int. Cl. H01L 27/12

(52) U.S. Cl. CPC H01L 27/1248; H01L 27/1288; H01L 27/124

(57) ABSTRACT

An array substrate, a method for manufacturing an array substrate, a display panel and a display device are provided. The array substrate includes a substrate; an insulating layer arranged at a side of the substrate, where the insulating layer is provided with an opening, the insulating layer includes a first area and a second area, a thickness of the first area is less than a thickness of the second area, and the first area is arranged around at least a part of the opening; and a first conductive part arranged at a side of the insulating layer away from the substrate, where an orthographic projection of the first conductive part on the substrate and an orthographic projection of the first area on the substrate are at least partially overlapped.

This application claims priority to Chinese Patent Application No. 202410109528.6, titled “ARRAY SUBSTRATE AND METHOD FOR MANUFACTURING THE SAME, DISPLAY PANEL AND DISPLAY DEVICE”, filed on Jan. 25, 2024 with the China National Intellectual Property Administration, which is hereby incorporated by reference in its entirety.

### FIELD

The present disclosure relates to the field of display devices, and in particular to an array substrate, a method for manufacturing an array substrate, a display panel and a display device.

### BACKGROUND

With the continuous development of display panel technology, requirements for the yield of display panels have been raising. To improve the display effect of a display area, components without display functions are generally arranged in a non-display area, and the components in the display area are connected to those in the non-display area through signal wires.

In conventional technology, the display area and/or non-display area is provided with openings, and the signal wires located in different layers are connected with each other through the structure of the openings to transmit signals. In practical scenario, the signal wires adjacent to the opening area are more likely to be disconnected, which causes a low yield of the display panels.

### SUMMARY

An array substrate, a method for manufacturing an array substrate, a display panel and a display device are provided according to embodiments of the present disclosure, which are interested in how to solve the problem of a low yield of the display panels due to metal wires in the display panel being more likely to be disconnected.

In the embodiments of the present disclosure, an array substrate is provided, the array substrate includes a substrate; an insulating layer, arranged at a side of the substrate, wherein the insulating layer is provided with an opening, and the insulating layer comprises a first area and a second area, wherein a thickness of the first area is less than a thickness of the second area, and the first area is arranged around at least a part of the opening; and a first conductive part, arranged at a side of the insulating layer away from the substrate, wherein an orthographic projection of the first conductive part on the substrate and an orthographic projection of the first area on the substrate are at least partially overlapped.

In the embodiments of the present disclosure, a display panel is further provided, including the array substrate according to any one of embodiments.

In the embodiments of the present disclosure, a display device is further provided, including the display panel in the above embodiments.

In the embodiments of the present disclosure, a method for manufacturing an array substrate is further provided, including:
providing an insulating material layer on a substrate;
patterning the insulating material layer to form an insulating layer including an opening, a first area and a second area, a thickness of the first area is less than a thickness of the second area, and the first area is arranged around at least a part of the opening;
providing a conductive material layer at a side of the insulating layer away from the substrate; and
patterning the conductive material layer to form a first conductive part, wherein an orthographic projection of the first conductive part on the substrate and an orthographic projection of the first area on the substrate are at least partially overlapped.

### BRIEF DESCRIPTION OF THE DRAWINGS

Embodiments of the present disclosure will become clearer after reading the detailed description of non-restricted embodiments in conjunction with the drawings, where identical or similar reference signs in the drawings indicate identical or similar features.

FIG. 1 is a schematic structural diagram of an array substrate according to an embodiment of the present disclosure;

FIG. 2 is a schematic structural diagram of a partially enlarged view of a position P shown in FIG. 1;

FIG. 3 is a section view in an A-A direction shown in FIG. 2;

FIG. 4 is a schematic structural diagram of a partially enlarged view of a position P shown in FIG. 1 according to another embodiment of the present disclosure;

FIG. 5 is a section view in a B-B direction shown in FIG. 4;

FIG. 6 is a schematic structural diagram of a partially enlarged view of a position P shown in FIG. 1 according to still another embodiment of the present disclosure;

FIG. 7 is a section view in a C-C direction shown in FIG. 6 according to an embodiment of the present disclosure;

FIG. 8 is a section view in a C-C direction shown in FIG. 6 according to another embodiment of the present disclosure;

FIG. 9 is a schematic structural diagram of a partially enlarged view of a position P shown in FIG. 1 according to yet another embodiment of the present disclosure;

FIG. 10 is a section view in a D-D direction shown in FIG. 9 according to an embodiment of the present disclosure;

FIG. 11 is a schematic structural diagram of a partially enlarged view of a position P shown in FIG. 1 according to yet another embodiment of the present disclosure;

FIG. 12 is a section view in an E-E direction shown in FIG. 11 according to an embodiment of the present disclosure;

FIG. 13 is a schematic structural diagram of a display panel according to an embodiment of the present disclosure;

FIG. 14 is a schematic structural diagram of a display device according to an embodiment of the present disclosure;

FIG. 15 is a schematic flowchart of a method for manufacturing an array substrate according to an embodiment of the present disclosure;

FIG. 16 is a schematic flowchart of a step of a method for manufacturing an array substrate according to an embodiment of the present disclosure;

FIG. 17 and FIG. 18 are schematic structural diagrams of manufacturing processes of a method manufacturing an array substrate in FIG. 16;

FIG. 19 is a schematic flowchart of a step of a method for manufacturing an array substrate according to another embodiment of the present disclosure; and

FIG. 20 is a schematic structural diagram of manufacturing processes of a method for manufacturing an array substrate in FIG. 19.

### REFERENCE SIGNS IN THE DRAWINGS

10: Array substrate; 20: Display panel; 30: Display device;
100: Substrate;
200: Insulating layer; 201: Recess; 210: Opening; 211: First opening; 212: Second opening; 213: Third opening; 220: First area; 230: Second area;
300: First conductive part; 310: First segment; 311: First sub-segment; 312: Second sub-segment; 320: Second segment;
400: Control chip;
500: Second conductive part;
600: First mask plate; 610: First via; 620: First light-shielding area; 630: Second light-shielding area;
700: Second mask plate; 710: Second via; 720: Third light-shielding area; 721: Slit; 730: Fourth light-shielding area; and
X: First direction; Y: Second direction.

### DETAILED DESCRIPTION

The features and exemplary embodiments of the present disclosure are described in detail below. In the following detailed description, many specific details are provided to facilitate full understanding of the present disclosure. The present disclosure may be implemented without some of these specific details. The description of the exemplary embodiments is only intended to provide a better understanding of the present disclosure. In the drawings and the following description, at least part of well-known structures and techniques are omitted to avoid unnecessarily obscuring the present disclosure. In addition, sizes of part of structures may be enlarged for clarity. Furthermore, the described features, structures, or characteristics may be combined in any suitable manner in one or more embodiments.

In the description of the present disclosure, it should be noted that “multiple” refers to at least two. Unless otherwise noted; the orientation or positional relationships indicated by terms such as “up”, “down”, “left”, “right”, “inner”, “outer” and the like are merely for the convenience of describing the present disclosure and the simplification of the description rather than indicating or implying that the device or component referred must be arranged in a particular orientation, or be constructed and operated in a particular orientation, and therefore should not be construed as a limitation to the present disclosure. In addition, the terms “first”, “second” and the like are for purpose of description, and should not be construed as indicating or implying relative importance.

All orientation words used in the following description are the directions shown in the drawings and are not intended to limit the specific structures of the embodiments of the present disclosure. In a description of the present disclosure, it should be further noted that, unless otherwise explicitly specified and located, terms such as “install” and “connect” should be understood in a broad sense, for example, the terms may imply a fixed connection, a detachable connection, or an integral connection; may imply a direct connection or an indirect connection. The specific meaning of the above terms in the present disclosure may be understood under specific circumstances.

In conventional technology, part of the insulating film layers of the display area and/or the non-display area in the display panel are provided with openings. For example, openings are arranged on the insulating film layer of the non-display area to accommodate components such as a control chip, and openings are arranged on the film layer of the display area and the wiring in different layers can be connected to each other through the openings. In practical scenario, the signal wiring around the peripheral side of the openings are more likely to be disconnected, e.g., the signal wiring may be broken, resulting in a low yield of the display panels.

In a case that conductive wiring is required to be manufactured on the insulating film layer with vias, the inventor found that in a case that the conductive material is patterned to manufacture the metal wiring by using photoresist and the like processes or techniques, the photoresist may flow into the vias due to the existence of the openings, causing the conductive material, which should be covered by photoresist during the manufacturing process, is exposed and etched, affecting the yield of conductive wiring, resulting in the problems such as disconnection, e.g., wiring breakage, thereby compromising the overall yield of the display panels.

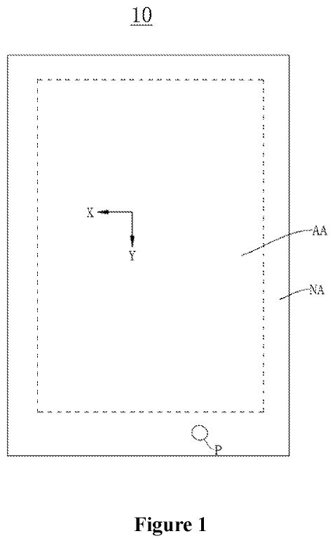

In order to more clearly understand the present disclosure, a display panel 20, a display device 30, an array substrate 10 and a method for manufacturing the array substrate are described in detail below in conjunction with the FIGS. 1 to 20.

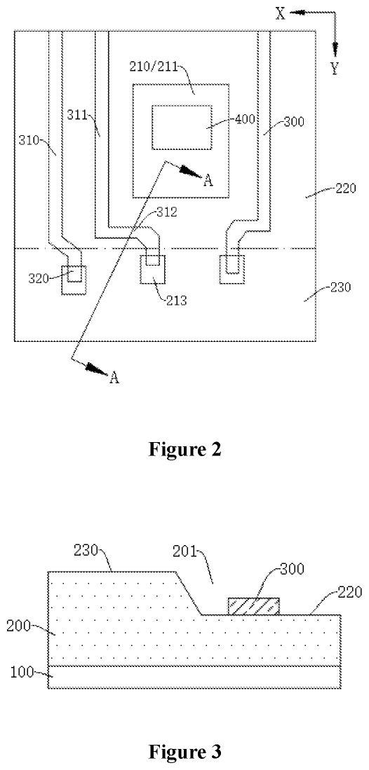

Reference is made to FIGS. 1 to 3. FIG. 1 is a schematic structural diagram of an array substrate 10 according to an embodiment of the present disclosure. FIG. 2 is a schematic structural diagram of a partially enlarged view of a position P shown in FIG. 1. FIG. 3 is a section view in an A-A direction shown in FIG. 2. FIG. 1 illustrates the position P located in the non-display area NA as an example. In other embodiments, the position P may further be located in the display area AA, and the position P may be partially located in the display area AA and partially located in the non-display area NA. As shown in FIG. 1 to FIG. 3, the array substrate 10 provided in an embodiment of the present disclosure includes a substrate 100, an insulating layer 200, and a first conductive part 300. The insulating layer 200 is arranged at a side of the substrate 100, and the insulating layer 200 is provided with an opening 210. The insulating layer 200 includes a first area 220 and a second area 230. The thickness of the first area 220 is less than the thickness of the second area 230, and the first area 220 are arranged around at least a part of the opening 210. A first conductive part 300 is arranged at a side of the insulating layer 200 away from the substrate 100, where an orthographic projection of the first conductive part 300 on the substrate 100 at least partially and an orthographic projection of the first area 220 on the substrate 100 are overlapped. The dividing line between the first area 220 and the second area 230 is indicated in a dash-dotted line as shown in FIG. 2.

According to an embodiment of the present disclosure, the array substrate 10 includes a substrate 100, an insulating layer 200 arranged on the substrate 100 and a first conductive part 300. The first conductive part 300 is arranged at a side of the insulating layer 200. In a case of manufacturing the first conductive part 300, the conductive material on the insulating layer 200 may be patterned to form the first conductive part 300. The insulating layer 200 is provided with the first area 220 and the second area 230, and the first area 220 is arranged around at least a part of the openings 210, and a distance from the first area 220 to the opening 210 is less than a distance from the second area 230 to the opening 210. In this way, material on the first area 220 is more likely to flow into the opening 210. An orthographic projection of the first conductive part 300 on the substrate 100 and an orthographic projection of the first area 220 on the substrate 100 are at least partially overlapped, i.e., the first conductive part 300 is located on the first area 220. During the process of patterning the conductive material covered by photoresist on the first area 220 to form the first conductive part 300, the photoresist is more likely to flow into the opening 210, which may cause the conductive material to be over-etched, resulting in faults such as the disconnection of the first conductive part 300. In view of this, in an embodiment of the present disclosure, the thickness of first area 220 is configured to be less than the thickness of the second area 230. In this way, due to a levelling property of the photoresist, a relatively large amount of photoresist can be provided within the first area 220. Even if a part of the photoresist flows toward the opening 210, sufficient photoresist material will be covered on the conductive material, which can prevent the conductive material in the first area 220 from being over-etched, to improve the yield of the first conductive part 300. In addition, since the thickness of the first area 220 is minor, and a thickness difference between the first area 220 and the opening 210 is minor, which can slow down the flow speed of the photoresist and further prevent the conductive material in the first area 220 from being over-etched, and the yield of the first conductive part is improved. Furthermore, with the minor thickness of the first area, a relatively large difference in thickness between a surface of the insulating layer 200 away from the substrate 100 and the opening 210 is divided into at least two minor differences in thickness. By doing so, it can further reduce the flow speed of the photoresist. Consequently, the conductive material in the first area 220 is prevented from being over-etched, which improves the yield of the first conductive part. Therefore, according to the embodiment of the present disclosure, a local thickness of the insulating layer 200 under the first conductive part 300 is reduced, which can improve the low yield caused by the first conductive part 300 is more likely to be disconnected.

According to an embodiment of the present disclosure, in a case of manufacturing the first conductive part 300 on the insulating layer 200, the insulating layer 200 may be patterned first to form the opening 210, the first area 220 and the second area 220. For example, the opening 210 and the first area 220 may be formed respectively through the double-etching process. In one embodiment, the opening 210 and the first area 220 may be formed through the semi-etching process. Then a conductive material layer is arranged on the insulating layer 200. Subsequently, a photoresist material layer is coated on the conductive material layer, and the photoresist layer is formed by patterning the photoresist material layer. Finally, the area of the conductive material that is not covered by the photoresist layer is removed, and the conductive material covered by the photoresist layer is remained to form the first conductive part 300. In a case that the conductive material of the first area 220 is coated with photoresist to manufacture the first conductive part 300, due to the small thickness of the first area 220, the photoresist layer in the first area 220 may be thicker, the thickness of the photoresist layer in the first area 220 is greater than the thickness of the photoresist layer in the second area 230. In this way, even if a part of the photoresist material in the first area 220 flows toward, e.g., the opening 210, there will be photoresist layer sufficiently covered on the conductive material. In addition, due to the minor thickness of the first area 220, the difference in thickness between the first area 220 and the opening 210 is minor, which can further reduce the flow speed of the photoresist layer toward the opening 210, and the conductive material in the first area 220 is prevented from being over-etched, and the yield of the first conductive part 300 is improved. Furthermore, with the minor thickness of the first area, a relatively large difference in thickness between a surface of the insulating layer 200 away from the substrate 100 and the opening 210 is divided into at least two minor differences in thickness. By doing so, it can further reduce the flow speed of the photoresist. Consequently, the conductive material in the first area 220 is prevented from being over-etched, which improves the yield of the first conductive part 300. In an embodiment, the insulating layer 200 is provided with an upper surface away from the substrate 100. The thickness of the first area 220 is less than that of the second area 230, consequently, an upper surface of the insulating layer 200 located in the first area 220, is located at a side of an upper surface of the insulating layer 200 located in the second area 230 adjacent to the substrate 100. In other words, a distance between the upper surface of the insulating layer 200 located in the first area 220 and the substrate 100 is less than a distance between the upper surface of the insulating layer 200 located in the second area 230 and the substrate 100. The upper surface of the insulating layer 200 forms a recess 201 in the first area 220, and more photoresist material for covering the first conductive part 300 is able to fall within the recess 201.

The insulating layer 200 may be made of organic material or inorganic material. For example, the insulating layer 200 may be made of a material including but is not limited to polyimide, polyethylene, polyvinylidene difluoride, polyteflon, silicon oxide, silicon nitride, or the like. The insulating layer 200 may arranged to be adjacent to the substrate 100, or other film layers may be arranged between the insulating layer 200 and the substrate 100.

The first conductive part 300 may be arranged in multiple manners. The first conductive part 300 may be configured to transmit a data signal, a scanning signal, and a power supply voltage signal and the like. The types of the signal transmitted by the first conductive part 300 are not limited in the present disclosure. The first conductive part 300 may be configured to transmit the same signal. In one embodiment, in a case that the number of the first conductive parts 300 is more than one, different first conductive parts 300 may be configured to transmit different signals. The first conductive part 300 may be in a straight line shape, or the first conductive part 300 may further be in a shape of curved line, a zigzag line and other irregular shapes. The number of the first conductive parts 300 is one or more than one. For example, at least two first conductive parts 300 may be arranged side by side at a side of the opening 210 or at a peripheral side of the opening 210. The first area 220 may be arranged around a part of the opening 210. For example, in a case that the first conductive part 300 is arranged around a part of opening 210, the first area 220 may be arranged around a part of the opening 210. In an embodiment, in a case that the first conductive parts 300 are arranged at different sides of the opening 210, the first area 220 may be arranged around the peripheral side of the opening 210, as long as a thinned first area 220 is arranged under part of the first conductive parts 300 which are arranged around the opening 210.

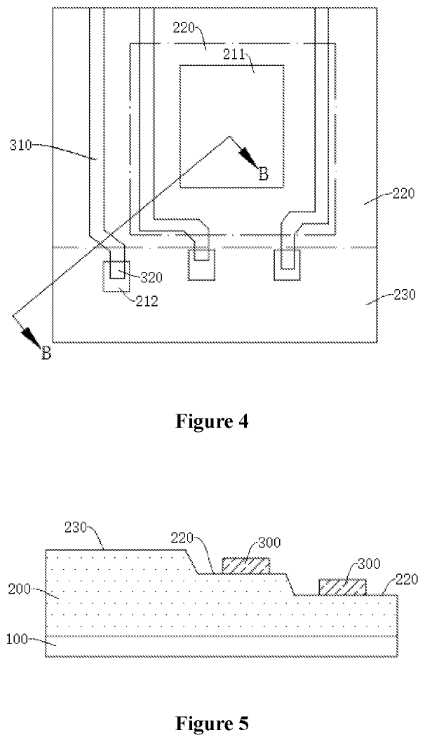

The number of the first areas 220 may be one or more. Reference is made to FIGS. 1 to 5. The number of first areas 220 is more than one, and multiple first areas 220 may be arranged side by side in a direction away from the opening 210. By arranging multiple first areas 220, the thicknesses of the insulating layers 200 in multiple areas can be thinned, to better prevent the problem that the first conductive part 300 is more likely to be disconnected. The dividing lines between different first areas 220 are indicated in dash-dotted lines as shown in FIG. 4.

Furthermore, by arranging multiple first areas 220, different degrees of compensation can be achieved for the line width in the same area. By reasonably adjusting the position of the first area 220, the first conductive part 300 at different positions or different positions of the first conductive part 300 can be compensated in different degrees, better preventing the first conductive part 300 from being disconnected such as broken.

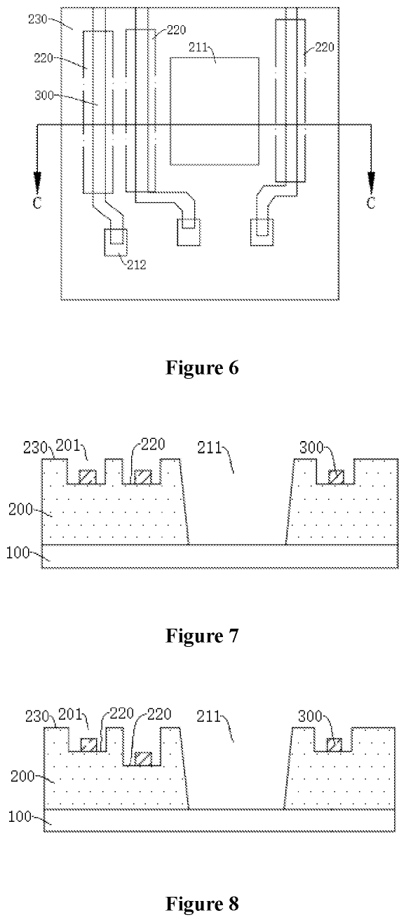

In a case that the number of the first areas 220 is more than one, as shown in FIG. 6 and FIG. 7, multiple first areas 220 may be spaced in a direction away from the opening 210, the first conductive part 300 is arranged correspondingly in at least part of the first areas 220. For example, the first conductive part 300 is arranged in each first area 220.

In these embodiments, by spacing multiple first areas 220 and configuring the first conductive parts 300 in the first areas 220 correspondingly, multiple first conductive parts 300 are provided with corresponding first areas 220, which can prevent the first conductive parts 300 from being disconnected.

In these embodiments, by configuring recesses at specific locations to form multiple first areas 220 spaced instead of reducing the overall thickness of local insulating layer 200, the first conductive parts 300 in different line widths can be compensated to prevent the first conductive parts 300 from being disconnected. In addition, the impact of thinning insulating layer 200 on the overall flatness of the insulating layer 200 can be weaken, which can ensure the flatness of the surface of the insulating layer 200 away from the substrate 100 and reduce the negative impact caused by thinning the insulating layer 200.

In an embodiment, among the spaced multiple first areas 220, the first conductive part 300 is arranged in each first area 220, i.e., different first conductive parts 300 corresponds to different first areas 220. In this way, the problem of first conductive parts 300 being more likely to be disconnected can be prevented by the first areas 220.

In a case that the number of the first areas 220 is more than one, the multiple first areas 220 may be of the same thickness. For example, multiple first areas 220 in the same thickness are spaced.

In other embodiments, as shown in FIG. 4 and FIG. 5, in a case that the number of the first areas 220 is more than one, the thicknesses of the first areas 220 are gradually decreased in a direction of approaching the opening 210.

In these embodiments, as approaching the first area 220, the photoresist layer on the insulating layer 200 is more likely to flow toward the opening 210, where the photoresist layer is configured to cover on the conductive material to manufacture the first conductive part 300, causing that the first conductive part 300 is more likely to be disconnected. By gradually decreasing the thicknesses of the first areas 220 in the direction of approaching the opening 210, the thickness of the photoresist layer on the first conductive part is increased in the direction of approaching the opening 210, to better prevent the problem that the first conductive part 300 is more likely to be disconnected. In addition, as the thicknesses of the first areas 220 are gradually decreased in the direction of approaching the opening 210, the difference in thickness between the opening 210 and the first area 220 closer to the opening 210 is reduced, further slowing down the flow speed of the photoresist layer.

In a case that the thicknesses of the first areas 220 are gradually decreased, the multiple first areas 220 may be adjacent, and the surface of the insulating layer 200 away from the substrate 100 forms a step shape. In an embodiment, one or more first conductive parts 300 may be arranged at each step.

In an embodiment, as shown in FIG. 8, in a case that the thicknesses of the first areas 220 are gradually decreased, these multiple first areas 220 may be spaced, and each first area 220 forms a recess 201 at the surface of the insulating layer 200 away from the substrate 100, and multiple recesses 201 are formed on the insulating layer 200. One or more first conductive parts 300 may be arranged in each recess 201.

In an embodiment, there are various positions for arranging the opening 210. The opening 210 may be located in the display area or non-display area of the display panel 20. The relative position relationship between the opening 210 and the first conductive part 300 may be arranged in multiple manners. The first conductive part 300 may be arranged around the opening 21. In one embodiment, the orthographic projection of the first conductive part 300 on the substrate 100 and the orthographic projection of the opening 210 on the substrate 100 may be at least partially overlapped.

In some embodiments, as shown in FIGS. 1 to 8, the opening 210 include a first opening 211, the first conductive parts 300 and the first opening 211 are spaced, and at least part of the first conductive parts 300 are arranged around the first opening 211.

In these embodiments, the first conductive part 300 is arranged around at least part of the first opening 211. During the manufacturing process of the first conductive part 300, the photoresist layer covering the first conductive part of the conductive material is more likely to flow toward the first opening 211, causing disconnection of the first conductive part. According to the embodiment, by arranging the thinned first area 220 around the first opening 211 and the first conductive part 300 arranged on the first area 220, more photoresist layers is remained on the first area 220, it further prevent the problem of disconnection of the first conductive part 300 due to the photoresist layer is more likely to flow toward the first opening 211.

The first conductive part 300 may be arranged around the first opening 211 in multiple manners. The first conductive part 300 may be in a straight line shape and arranged at a side of the first opening 211.

In other embodiments, as shown in FIG. 2, the first conductive part 300 includes a first segment 310 and a second segment 320 connected in sequence. The first segment 310 is arranged around the first opening 211, and the second segment 320 is connected to a terminal of the first segment 310, and is extend and formed in a direction away from the first opening 211. An orthographic projection of the first segment 310 on the substrate 100 and an orthographic projection of the first area 220 on the substrate 100 are at least partially overlapped.

In these embodiments, the first conductive part 300 includes the first segment 310 and the second segment 320. Since the first segment 310 is arranged around the first opening 211 and the second segment 320 is arranged away from the first opening 211, the first segment 310 is more likely to be disconnected during manufacture. By configuring the orthographic projection of the first segment 310 on the substrate 100 to be at least partially overlapped with the orthographic projection of the first area 220 on the substrate 100, i.e., the first segment 310 is located on the first area 220, it can prevent the problem that the first segment 310 is more likely to be disconnected.

In an embodiment, the orthographic projection of the second segment 320 on the substrate 100 and the orthographic projection of the second area 230 on the substrate 100 are at least partially overlapped. In other words, the second segment 320 is located on the second area 230. Where, the second segment 320 is manufactured according to normal process. Although more manufacture material of the first segment 310 is used due to the first segment 310 is arranged on the first area 220, as the photoresist layer covered on the conductive material for manufacturing the first segment 310 flows toward the opening 210, a thickness of the photoresist layer covered the conductive material for manufacturing the first segment 310 and that of the photoresist layer covered the conductive material for manufacturing the second segment 320 in the unit length are substantially identical, and the line width of the first segment 310 of the first conductive part 300 is substantially identical to the line width of the second segment 320 of the first conductive part 300, which improves the uniformity of the distribution of the first conductive part 300.

The first segment 310 may be in a straight-line shape.

In other embodiments, as shown in FIG. 2, the first segment 310 may include a first sub-segment 311 and a second sub-segment 312, where the first sub-segment 311 is located at a side of the first opening 211 in a first direction X, and the first sub-segment 311 is extended and formed in a second direction Y. The second sub-segment 312 is located at a side of the first opening 211 in the second direction Y, and the second sub-segment 312 is extended and formed in the first direction X. The second segment 320 is connected to a terminal of the second sub-segment 312 away from the first segment 310, and is extended and formed in the second direction Y away from the first opening 211.

In these embodiments, the first segment 310 is in a shape of zigzag line and includes the first sub-segment 311 and the second sub-segment 312. The first sub-segment 311 and the second sub-segment 312 are arranged at different positions around the first opening 211. The first sub-segment 311 and the second sub-segment 312 are extended and are formed in different directions. An orthographic projection of the first sub-segment 311 and the second sub-segment 312 on the substrate 100 at least partially overlaps with the orthographic projection of the second area 230 on the substrate 100, which prevents the problem that the first sub-segment 311 and the second sub-segment 312 are more likely to be disconnected.

In some embodiments, the opening 210 further includes a second opening 212. An orthographic projection of the second opening 212 on the substrate 100 at least partially overlaps with an orthographic projection of the second segment 320 on the substrate 100. A minimum distance between the first opening 211 and the second opening 212 is greater than or equal to 25 μm.

In these embodiments, the orthographic projection of the second opening 212 on the substrate 100 and the orthographic projection of the second segment 320 on the substrate 100 are at least partially overlapped, and at least part of the second segment 320 passes through the second opening 212. The first conductive part 300 is at least partially arranged between the first opening 211 and the second opening 212. By configuring the minimum distance between the first opening 211 and the second opening 212 greater than or equal to 25 μm, it can leave sufficient space to arrange the first conductive part 300. In this way, it can prevent the problem of the first conductive part 300 being more likely to be disconnected due to the first conductive part 300 and the first opening 211 are too close.

In an embodiment, as described above, the array substrate 10 includes a display area and a non-display area arranged around at least a part of the display area, and the first opening 211 may be located in the non-display area. In a case that the first opening 211 is located in the non-display area, the first opening 211 may be used to accommodate a control chip 400. In other words, the control chip 400 may be a sunken/embedded control chip 400. In an embodiment, the first conductive part 300 may include a fanout line, which is arranged in the non-display area around the first opening 211, where the first opening 211 is configured to accommodate the control chip 400. In this case, the fanout line may be disconnected easily. According to an embodiment, the thickness of the first area 220 is reduced to prevent the fanout line from being disconnected.

In some embodiments, a minimum distance between the first conductive part 300 and the first opening 211 is greater than or equal to 8 μm.

In conventional technology, since the distance between the first conductive part 300 and the first opening 211 is minor, the photoresist layer covered on the conductive material for manufacturing the first conductive part 300 is more likely to flow into the first opening 211, resulting in first conductive part 300 being more likely to be disconnected. In these embodiments of the present disclosure, by configuring the minimum distance between the first conductive part 300 and the first opening 211 to meet the above requirement, it can prevent the above problem of the first conductive part 300 being more likely to be disconnected.

In an embodiment, in a case that the first opening 211 is located in the non-display area, for example, in a case that the first opening 211 is located in the non-display area and is configured to accommodate the control chip 400, the minimum distance between the first conductive part 300 and the first opening 211 may be ensured to be greater than or equal to 8 μm by reducing the size of the first opening 211. For example, the width of the first opening 211 in the first direction may be reduced to 5.6 μm approximately, to ensure that the minimum distance between the first opening 211 and the first sub-segment 311 of the first conductive part 300 is greater than or equal to 8 μm. By reducing the size of the first opening 211, the amount of the photoresist layer flowing into the first opening 211 may further be reduced, where the photoresist layer is covered on the conductive material for manufacturing the first conductive part 300, to prevent the problem of the first conductive part 300 being more likely to be disconnected. In an embodiment, the first opening 211 may be located in the display area, and the minimum distance between the first conductive part 300 and the first opening 211 may be adjusted. By reducing the size of the first opening 211, the amount of the photoresist layer flowing into the first opening 211 may further be reduced, where the photoresist layer is covered on the conductive material for manufacturing the first conductive part 300, to prevent the problem that the first conductive part 300 being more likely to be disconnected.

In some embodiments, the number of first conductive parts 300 is greater than one, and a minimum distance between two adjacent first conductive parts 300 is greater than or equal to 4 μm. In this way, it can prevent the problem that two adjacent first conductive parts 300 are more likely to occur short-circuit connection due to the excessively minor distance between the two adjacent first conductive parts 300.

In an embodiment, the distance between two adjacent first conductive parts 300 may be set to 5 μm, to prevent the problem of short-circuiting between them. The distance between two adjacent first conductive parts 300 may be altered by changing a mask plate used for manufacturing the first conductive part 300. It has been verified that the defect rate primarily due to the short-circuiting connection between the two adjacent first conductive parts 300 is decreased from 16% to 0% after increasing the distance between the two adjacent first conductive parts 300 to 5 μm, showing a significant and effective improvement.

In any one of the above embodiments, in a case that the first conductive part 300 is arranged around the first opening 211, the first conductive part 300 may be a signal wire. For example, the first conductive part 300 is located in the non-display area NA and is a fanout line. The first conductive part 300 may further be part of the signal wire or a pixel driving circuit in the display panel. For example, the first conductive part 300 is located in the display area AA and is a source terminal or a drain terminal of the transistor.

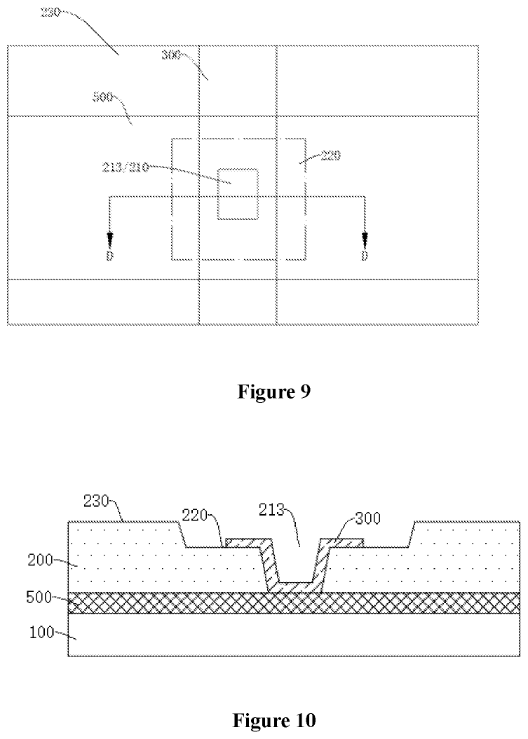

In some embodiments, as shown in FIG. 9 and FIG. 10, the opening 210 includes a third opening 213, the orthographic projection of the third opening 213 on the substrate 100 and the orthographic projection of the first conductive part 300 on the substrate 100 are at least partially overlapped, and the first area 220 is arranged around the third opening 213 and adjacent to the third opening 213.

In these embodiments, an orthographic projection of the third opening 213 on the substrate 100 at least partially overlaps with the orthographic projection of the first conductive part 300 on the substrate 100, that is, the first conductive part 300 is arranged through the third opening 213. The first area 220 is arranged around the third opening 213 and adjacent to the third opening 213, i.e., no interval between the first area 220 and the third opening 213. The material used for manufacturing the first conductive part 300 is relatively thick at the peripheral side of the third opening area 213. In this way, it can prevent the first conductive part 300 adjacent to the third opening 213 from being disconnected. In some embodiments, the array substrate 10 further includes a second conductive part 500, which is arranged at a side of the insulating layer 200 facing the substrate 100. The second conductive part 500 overlaps with the first conductive part 300 to form an overlapped area. The orthographic projection of the third opening 213 on the substrate 100 at least partially overlaps with an orthographic projection of the overlapped area on the substrate 100, and the first conductive part 300 is connected to the second conductive part 500 through the third opening 213.

In these embodiments, the second conductive part 500 is located at a side of the insulating layer 200 facing the substrate 100, i.e., the second conductive part 500 is located under the insulating layer 200. The second conductive part 500 and the first conductive part 300 above the insulating layer 200 are in the via-connection through the third opening 213. In other words, the third opening 213 is configured to connect the first conductive part 300 and the second conductive part 500.

The relative position relationship among the third opening 213, the first conductive part 300, and the second conductive part 500 may be arranged in multiple manners. For example, the first conductive part 300 and the second conductive part 500 extend in different directions and form an overlapped area. The orthographic projection of the third opening on the substrate 100 at least overlaps with the orthographic projection of the overlapped area on substrate 100, and the first conductive part 300 can be connected to the second conductive part 500 in the overlapped area.

The relative position relationship among the first area 220, the first conductive part 300 and the second conductive part 500 may be arranged in multiple manners. For example, the line width of first conductive part 300 is less than that of the second conductive part 500, and the orthographic projection of the first area 220 on the substrate 100 may be within the orthographic projection of the second conductive part 500 on the substrate 100. In other words, the first area 220 is correspondingly within the second conductive part 500. In one embodiment, in a case that the line width of first conductive part 300 is greater than the line width of second conductive part 500, the orthographic projection of the first area 220 on the substrate 100 may be arranged within the orthographic projection of the first conductive part 300 on the substrate 100, i.e., the first area 220 is correspondingly within the first conductive part 300. In other embodiments, the first area 220 may further be arranged to extend out of the first conductive part 300 or the second conductive part 500. In other words, the width of first area 220 is greater than the first conductive part 300 or the second conductive part 500.

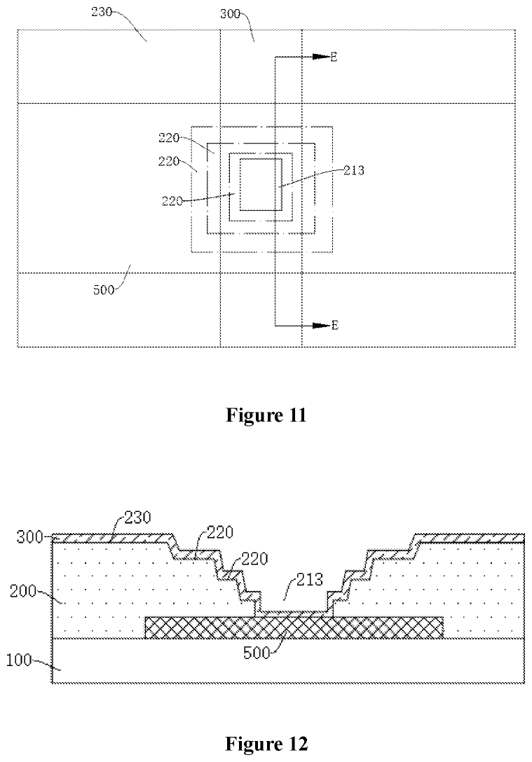

In an embodiment, as shown in FIG. 11 and FIG. 12, in a case that the opening 210 include the third opening 213, the number of the first areas 220 may be greater than one, and the thicknesses of multiple first areas 220 are gradually decreased in the direction of approaching the third opening 213.

In these embodiments, as approaching the third opening 213, the photoresist layer on the insulating layer 200 is more likely to flow into the third opening 213, where the photoresist layer is configured to cover on the conductive material to manufacture the first conductive part 300, causing the first conductive part 300 being more likely to be disconnected. By gradually decreasing the thicknesses of the first areas 220 in the direction of approaching the third opening 213, the thickness of the photoresist layer used for manufacturing the first conductive part 300 is increased in the direction of approaching the third opening 213. While manufacturing the first conductive part 300, sufficient photoresist layer can be remained on the conductive material, which can better prevent the first conductive part 300 from being disconnected.

In an embodiment, reference is made to FIG. 11 and FIG. 12. Multiple first areas 220 may be adjacent to each other, and the surface of the insulating layer 200 forms a step shape. In these embodiments, the third opening 213 is arranged corresponding to the same first conductive part 300, and multiple first areas 220 are arranged to be adjacent to each other instead of spacing, which can prevent the same first conductive part 300 for being disconnected.

In an embodiment, in a case that the number of the first conductive parts 300 is greater than one, and each first conductive part 300 is connected to the second conductive part 500 through the third opening 213, each first conductive part 300 is provided with a first area 220 correspondingly, to better prevent the disconnections of the multiple first conductive parts 300.

In a case that the first conductive part 300 and the second conductive part 500 are in the via-connection through the third opening 213, the first area 220 is arranged on the peripheral side of the third opening 213 to prevent the disconnection of the first conductive part 300 caused by the excessive depth of the third opening 213 while ensuring the performance of the array substrate 10.

In an embodiment, the third opening 213 may be located in the display area AA or the non-display area NA. As long as there are two signal wires via-connected through the third opening 213, a thinned first area 220 may be arranged at the peripheral side of the third opening 213. For example, the third opening 213 is located in the display area AA, the first conductive part 300 and the second conductive part 500 transmit the same signal. For example, the first conductive part 300 and the second conductive part 500 may be configured to transmit data signals, or transmit scanning signals, or transmit power supply voltage signals and the like. The third opening 213 may further be located in the non-display area NA, and the first conductive part 300 and the second conductive part 500 may be fan-out lines and configured to transmit data signals.

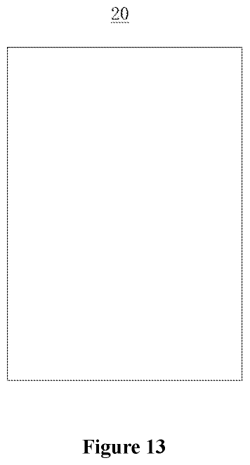

In an embodiment, the third opening 213 may be located in the display area AA or the non-display area NA, as long as there are different-layer structures via-connected through the third opening 213, a thinned first area 220 may be arranged at the peripheral side of the third opening 213. In an embodiment, the first conductive part 300 and the second conductive part 500 may be signal wires arranged in different layers. For example, the first conductive part 300 and the second conductive part 500 may be power supply voltage signal wires. In one embodiment, the first conductive part 300 and the second conductive part 500 may be a non-wired conductive structure and a signal wire arranged in different layers. For example, one of the first conductive part 300 and the second conductive part 500 is a signal wire, and the other is a conductive structure electrically connected to the signal wire. For example, one of the first conductive part 300 and the second conductive part 500 may be the source terminal of a transistor, and the other is a data signal wire. In one embodiment, the first conductive part 300 and the second conductive part 500 may further be two non-wired conductive structures arranged in different layers. For example, one of the first conductive part 300 and the second conductive part 500 is a drain terminal of the transistor, and the other is a connection part configured to be connected to a pixel electrode. According to an embodiment of the present disclosure, as long as the first conductive part 300 is via-connected to the second conductive part 500 through the third opening 213, the thinned first area 220 may be arranged at the peripheral side of the third opening 213, to prevent the problem that a wire or a non-wired conductive structure on the insulating layer is more likely to be disconnected. As shown in FIG. 13, a display panel 20 is further provided according to an embodiment of the present disclosure, the display panel 20 includes the array substrate 10 according to any one of the embodiments described above. Since the display panel 20 provided according to the embodiments of the present disclosure includes the array substrate 10 according to any one of the embodiments of the embodiments described above, the display panel 20 provided according to the embodiments of the present disclosure has the beneficial effects of the array substrate 10 according to any one of the embodiments described above, which will not be repeated herein.

In an embodiment, the display panel 20 may be at least one of a liquid crystal display panel, an organic light-emitting diode display panel or a micro light-emitting diode display panel. The display panel 20 may further be a transparent display panel, a splicing display panel and the like, as long as the display panel includes the array substrate.

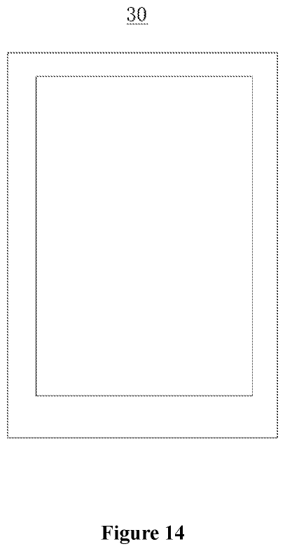

As shown in FIG. 14, a display device 30 is further provided according to embodiments of the present disclosure. Where, the display device 30 includes a display panel 20 according to any one of the embodiments described above. Since the display device 30 provided according to an embodiment of the present disclosure includes the display panel 20 according to any one of the embodiments described above, the display device 30 provided in the embodiments of the present disclosure has the beneficial effects of the display panel 20 according to any one of the embodiments described above, which will not be repeated herein.

In the embodiments of the present disclosure, the display device 30 includes but is not limited to a mobile phone, a personal digital assistant (PDA), a tablet computer, an e-book, a television set, an access control, a smart fixed phone, a console and other devices with display functions.

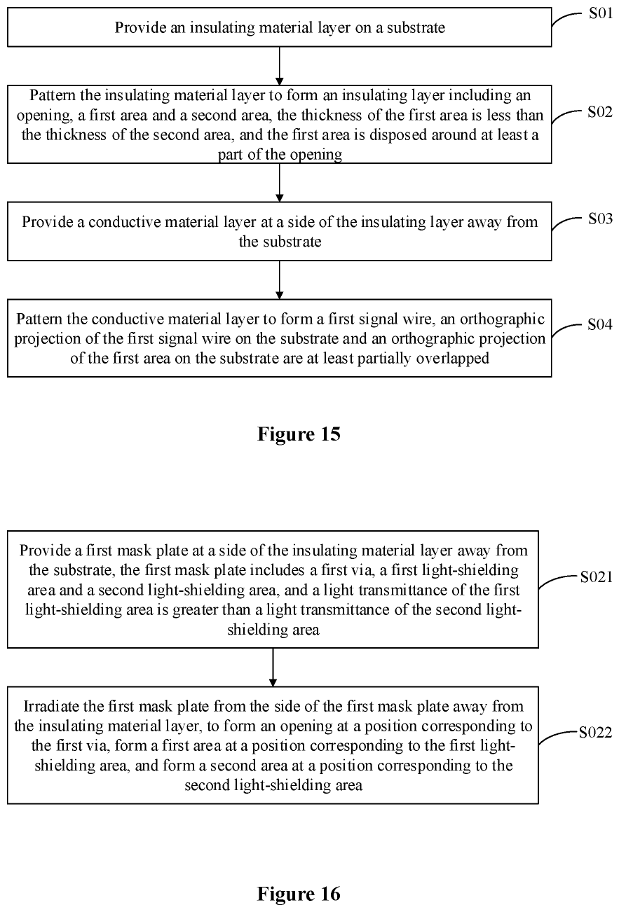

Reference is made to FIG. 15. FIG. 15 is a schematic flowchart of a method for manufacturing an array substrate 10 according to an embodiment of the present disclosure.

As shown in FIG. 15, according to the embodiments of the present disclosure, a method for manufacturing an array substrate 10 is further provided. The array substrate 10 may be the array substrate 10 provided according to any one of the embodiments described above. Reference is made to FIGS. 1 to 15, the method for manufacturing the array substrate 10 may include steps S01 to S04 as follows.

In step S01, an insulating material layer is provided on the substrate 100.

In step S02, the insulating material layer is patterned to form an insulating layer 200 including an opening 210, a first area 220 and a second area 230, where the thickness of the first area 220 is less than the thickness of the second area 230, and the first area 220 is arranged around at least a part of the opening 210.

In step S03, a conductive material layer is provided at a side of the insulating layer 200 away from the substrate 100.

In step S04, the conductive material layer is patterned to form the first conductive part 300, where an orthographic projection of the first conductive part 300 on the substrate 100 and an orthographic projection of the first area 220 on the substrate 100 are at least partially overlapped.

In the method for manufacturing the array substrate according to the embodiments of the present disclosure, an insulating material layer is first provided on the substrate 100, and then the insulating material layer is patterned to form an insulating layer 200 through step S02. The thickness of the first area 220 is less than the thickness of the second area 230, and the surface of the first area 220 away from the substrate 100 can form a recess 201. In step S04, a photoresist layer is provided at the side of the conductive material layer away from the insulating layer 200. When the conductive material layer is patterned by patterning the photoresist layer, the thickness of the photoresist layer in the first area 220 is relatively large. Even if part of the photoresist layer in the first area 220 flows toward the opening 210, sufficient photoresist layer is remained in the first area 220. In addition, due to the minor thickness of the first area 220, the difference in thickness between the first area 220 and the opening 210 is minor, which can slow down the flow speed of the photoresist layer between the first area 220 and the opening 210, to ensure that sufficient photoresist layer is remained in the first area 220. When the conductive material layer is patterned to form the first conductive part 300, the conductive material covered by the photoresist layer is remained and forms the first conductive part 300. Since sufficient photoresist layer is remained in the first area 220, the over-etching problem caused by insufficient photoresist layer on the first conductive part 300 can be improved, to prevent the first conductive part 300 layer on the first area 220 from disconnection.

In step S02, there are various methods for patterning the insulating material layer. For instance, the insulating material layer may undergo two patterning processes. In one patterning process, the opening 210 is formed. In the other patterning process, the first area 220 is formed. The area that is not subjected to patterning process forms a thicker second area 230.

In some embodiments, as shown in FIG. 16, step S02 may include steps S021 and S022 as follows.

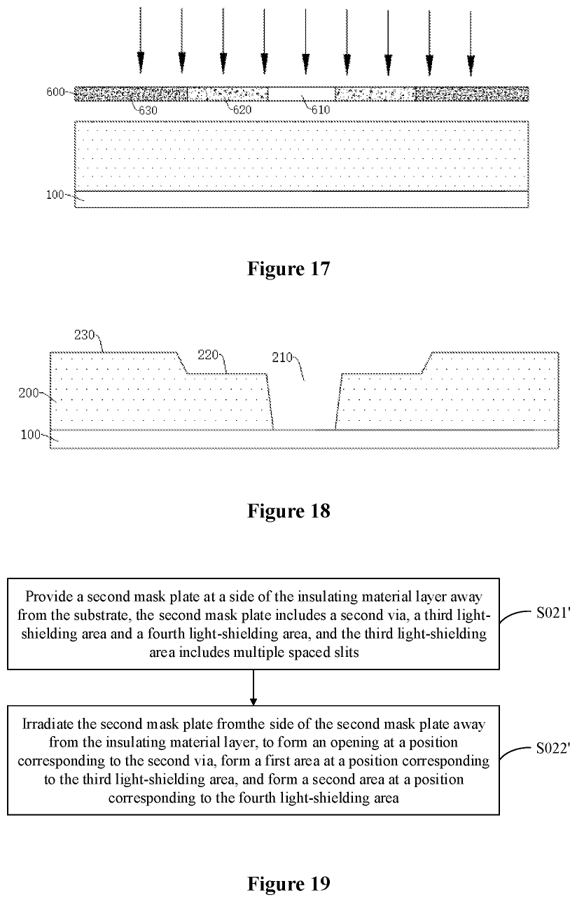

In step S021, as shown in FIG. 17, a first mask plate 600 is provided at a side of the insulating material layer away from the substrate 100. The first mask plate 600 includes a first via 610, a first light-shielding area 620 and a second light-shielding area 630. The light transmittance of the first light-shielding area 620 is greater than the light transmittance of the second light-shielding area 630.

In step S022, as shown in FIG. 18, the first mask plate 600 is irradiated from the side of the first mask plate 600 away from the insulating material layer to form the opening 210 at a position corresponding to the first via 610, the first area 220 is formed at a position corresponding to the first light-shielding area 620, and the second area 230 is formed at a position corresponding to the second light-shielding area 630.

In these embodiments, the first mask plate 600 is arranged on the insulating layer 200 through step S021, the first mask plate 600 has a fully transparent area (i.e., the first via 610), a semi-transparent area (i.e., the first light-shielding area 620), and an opaque area (i.e., the second light-shielding area 630). When the mask plate is irradiated in step S022, a greater amount of light passes through the first via 610 to form an opening 210 on the insulating layer 200, while a lesser amount of light passes through the first light-shielding area 620 to form the first area 220 on the insulating layer 200, and minimal to no light passes through the second light-shielding area 630 to form a thicker second area 230. According to an embodiment of the present disclosure, by arranging the first mask plate 600, the opening 210, the first area 220 and the second area 230 can be formed with just one patterning process, which can simplify the manufacture process of the insulating layer 200 and improve the manufacture efficiency of the array substrate 10.

In other embodiments, as shown in FIG. 19, step S02 may include steps S021′ and S022′ as follows.

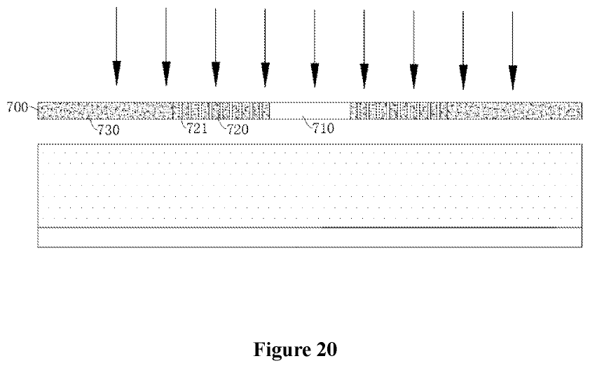

In step S021′, as shown in FIG. 20, a second mask plate 700 is provided at a side of the insulating material layer away from the substrate 100. The second mask plate 700 includes a second via 710, a third light-shielding area 720 and a fourth light-shielding area 730, and multiple slits 721 are spaced in the third light-shielding area 720.

In step S022′, as shown in FIG. 18, the second mask plate 700 is irradiated from the side of the second mask plate 700 away from the insulating material layer to form the opening 210 at a position corresponding to the second via 710, the first area 220 is formed at a position corresponding to the third light-shielding area 720, and the second area 230 is formed at a position corresponding to the fourth light-shielding area 730.

In these embodiments, a second mask plate 700 is first provided on the insulating layer 200 through step S021′. The second mask plate 700 has a fully transparent area and slit(s) 721, which, when light passes through, create diffraction, to remove part of the insulating material to form thinned first area(s) 220. Therefore, when the mask plate is irradiated in step S022′, a greater amount of light passes through the second via 710 to form an opening 210 on the insulating layer 200, while a lesser amount of light passes through the third light-shielding area 720 to form the first area 220 on the insulating layer 200, and minimal to no light passes through the fourth light-shielding area 730 to form a thicker second area 230. According to an embodiment of the present disclosure, by arranging the second mask plate 700, the opening 210, the first area 220 and the second area 230 can be formed with just one patterning process, which can simplify the manufacture process of the insulating layer 200 and improve the manufacture efficiency of the array substrate 10.

According to the embodiments of the present disclosure, the array substrate includes a substrate, an insulating layer arranged on the substrate and a first conductive part. The first conductive part is arranged at a side of the insulating layer. In a case of manufacturing the first conductive part, the conductive material on the insulating layer may be patterned to form the first conductive part. The insulating layer is provided with the first area and the second area, and the first area is arranged around at least a part of the opening, and a distance from the first area to the opening is less than a distance from the second area to the opening. In this way, material on the first area is more likely to flow into the opening. An orthographic projection of the first conductive part on the substrate and an orthographic projection of the first area on the substrate are at least partially overlapped, i.e., the first conductive part is located on the first area. During the process of patterning the conductive material covered by photoresist on the first area, the photoresist is more likely to flow into the opening, which may cause the conductive material to be over-etched, resulting in faults such as the disconnection of the first conductive part. In view of this, in the embodiments of the present disclosure, the thickness of first area is configured to be less than the thickness of the second area. In this way, a greater amount of photoresist can be provided within the first area. Even if a part of the photoresist flows toward the opening, sufficient photoresist material can cover the conductive material, which can prevent the conductive material in the first area from being over-etched, to improve the yield of the first conductive part. In addition, since the thickness of the first area is minor, and a thickness difference between the first area and the opening is minor, which can slow down the flow speed of the photoresist and further prevent the conductive material in the first area from being over-etched, and the yield of the first conductive part is further improved. Furthermore, with the minor thickness of the first area, a relatively large difference in thickness between a surface of the insulating layer away from the substrate and the opening is divided into at least two minor differences in thickness. By doing so, it can further reduce the flow speed of the photoresist. Consequently, the conductive material in the first area is prevented from being over-etched, which improves the yield of the first conductive part. Therefore, according to the embodiments of the present disclosure, a local thickness of the insulating layer under the first conductive part is thinned, which can improve the low yield caused by the first conductive part being more likely to be disconnected.

Although the present disclosure is described with reference to the embodiments, various improvements can be made to it and the components therein can be replaced with equivalents, without departing from the scope of the present disclosure. In particular, as long as there is no structural conflict, the various features mentioned in the various embodiments can be combined in any manner.

1. An array substrate, comprising:
a substrate;
an insulating layer, arranged at a side of the substrate, wherein the insulating layer is provided with an opening, the insulating layer comprises a first area and a second area, a thickness of the first area is less than a thickness of the second area, and the first area is arranged around at least a part of the opening; and
a first conductive part, arranged at a side of the insulating layer away from the substrate, wherein an orthographic projection of the first conductive part on the substrate and an orthographic projection of the first area on the substrate are at least partially overlapped.

2. The array substrate according to claim 1, wherein a number of the first area is plural, and a plurality of first areas are arranged side by side in a direction away from the opening.

3. The array substrate according to claim 2, wherein the plurality of first areas are spaced in the direction away from the opening, and the first conductive part is arranged in at least part of the plurality of the first areas.

4. The array substrate according to claim 2, wherein thicknesses of the plurality of the first areas are gradually decreased in a direction of approaching the opening.

5. The array substrate according to claim 4, wherein
the plurality of first areas are adjacent to each other to form a step-shaped surface of the insulating layer away from the substrate; or
the plurality of first areas are spaced.

6. The array substrate according to claim 1, wherein the opening comprises a first opening, the first opening and the first conductive part are spaced, and at least a part of the first conductive part is arranged around the first opening.

7. The array substrate according to claim 6, wherein the first conductive part comprises a first segment and a second segment connected in sequence, the first segment is arranged around the first opening, and the second segment is connected to a terminal of the first segment, wherein the second segment is extended and formed in a direction away from the first opening, an orthographic projection of the first segment on the substrate and the orthographic projection of the first area on the substrate are at least partially overlapped.

8. The array substrate according to claim 7, wherein the first segment comprises a first sub-segment and a second sub-segment, the first sub-segment is located at a side of the first opening in a first direction, and the first sub-segment is extended and formed in a second direction, the second sub-segment is located at a side of the first opening in the second direction, and the second sub-segment is extended and formed in the first direction, the second segment is connected to a terminal of the second sub-segment away from the first segment, the second segment is extended and formed in the second direction away from the first opening.

9. The array substrate according to claim 7, wherein the opening further comprises a second opening, an orthographic projection of the second opening on the substrate and an orthographic projection of the second segment on the substrate are at least partially overlapped, and a minimum distance between the first opening and the second opening is greater than or equal to 25 μm.

10. The array substrate according to claim 6, wherein the array substrate comprises a display area and a non-display area at least partially surrounded around the display area, and the first opening is located in the non-display area;
the first opening is configured to accommodate a control chip; and/or
the first conductive part comprises a fanout line.

11. The array substrate according to claim 6, wherein a minimum distance between the first conductive part and the first opening is greater than or equal to 8 μm.

12. The array substrate according to claim 6, wherein a number of the first conductive part is plural, and a minimum distance between two adjacent first conductive parts is greater than or equal to 4 μm.

13. The array substrate according to claim 1, wherein the opening comprise a third opening, an orthographic projection of the third opening on the substrate and the orthographic projection of the first conductive part on the substrate are at least partially overlapped, and the first area is arranged around the third opening and adjacent to the third opening.

14. The array substrate according to claim 13, further comprising:
a second conductive part, arranged at a side of the insulating layer facing the substrate, wherein the second conductive part and the first conductive part are overlapped to form an overlapped area, the orthographic projection of the third opening on the substrate and an orthographic projection of the overlapped area on the substrate are at least partially overlapped, and the first conductive part and the second conductive part is in a via-connection through the third opening.

15. A display panel, comprising an array substrate, wherein the array substrate comprises:
a substrate;
an insulating layer, arranged at a side of the substrate, wherein the insulating layer is provided with an opening, and the insulating layer comprises a first area and a second area, wherein a thickness of the first area is less than a thickness of the second area, and the first area is arranged around at least a part of the opening; and
a first conductive part, arranged at a side of the insulating layer away from the substrate, wherein an orthographic projection of the first conductive part on the substrate and an orthographic projection of the first area on the substrate are at least partially overlapped.

16. A display device, comprising the display panel according to claim 15.

17. A method for manufacturing an array substrate, comprising:
providing an insulating material layer on a substrate;
patterning the insulating material layer to form an insulating layer including an opening, a first area and a second area, a thickness of the first area is less than a thickness of the second area, and the first area is arranged around at least a part of the opening;
providing a conductive material layer at a side of the insulating layer away from the substrate; and
patterning the conductive material layer to form a first conductive part, wherein an orthographic projection of the first conductive part on the substrate and an orthographic projection of the first area on the substrate are at least partially overlapped.

18. The method for manufacturing the array substrate according to claim 17, wherein the patterning the insulating material layer to form the insulating layer including the opening, the first area and the second area comprises:
providing a first mask plate at a side of the insulating material layer away from the substrate, wherein the first mask plate comprises a first via, a first light-shielding area and a second light-shielding area, a light transmittance of the first light-shielding area is greater than a light transmittance of the second light-shielding area; and
irradiating the first mask plate from a side of the first mask plate away from the insulating material layer, to form the opening at a position corresponding to the first via, form the first area at a position corresponding to the first light-shielding area, and form the second area at a position corresponding to the second light-shielding area.

19. The method for manufacturing the array substrate according to claim 17, wherein the patterning the insulating material layer to form the insulating layer including the opening, the first area and the second area comprises:
providing a second mask plate at a side of the insulating material layer away from the substrate, wherein the second mask plate comprises a second via, a third light-shielding area and a fourth light-shielding area, and the third light-shielding area comprises a plurality of spaced slits; and
irradiating the second mask plate from a side of the second mask plate away from the insulating material layer, to form the opening at a position corresponding to the second via, form the first area at a position corresponding to the third light-shielding area, and form the second area at a position corresponding to the fourth light-shielding area.
